(19) United States
(12) Patent Application Publication
(10) Pub. No.: US 2021/0263071 A1
(43) Pub. Date: Aug. 26, 2021

(54) PROBE

(71) Applicant: Murata Manufacturing Co., Ltd., Kyoto-fu (JP)

(72) Inventors: Kiyoto ARAKI, Nagaokakyo-shi (JP); Jun TODA, Nagaokakyo-shi (JP)

(73) Assignee: Murata Manufacturing Co., Ltd., Kyoto-fu (JP)

(21) Appl. No.: 17/317,649

(22) Filed: May 11, 2021

Related U.S. Application Data
(63) Continuation of application No. PCT/JP2019/044262, filed on Nov. 12, 2019.

(30) Foreign Application Priority Data
Nov. 13, 2018 (JP) 2018-212924

(51) Int. Cl. G01R 1/067

(52) U.S. Cl. CPC G01R 1/06716; G01R 1/06772

(57) ABSTRACT

A probe is connected to a signal conductor of a signal cable when used, and is capable of coming into contact with a signal conductor of a mating receptacle. The probe includes a barrel that is a tubular conductor and that is electrically connectable to the signal conductor of the signal cable; a plunger that is a conductor and has a proximal end disposed in the barrel and a distal end projecting from the barrel and is configured to come into contact with the mating receptacle; and a coil spring disposed in the barrel. The coil spring urges the proximal end of the plunger in a direction toward the distal end of the plunger. The barrel includes a contact portion that is in contact with the plunger at a position closer to a distal end of the barrel than the proximal end of the plunger.

### CROSS-REFERENCE TO RELATED APPLICATIONS

This application claims benefit of priority to International Patent Application No. PCT/JP2019/044262, filed Nov. 12, 2019, and to Japanese Patent Application No. 2018-212924, filed Nov. 13, 2018, the entire contents of each are incorporated herein by reference.

### BACKGROUND

### Technical Field

The present disclosure relates to probes for testing electric and electronic circuits, and more specifically to a probe capable of being connected to a mating receptacle provided on a circuit board, which is a test subject.

### Background Art

A high-frequency coaxial probe and a spring connector (pogo pin) according to the related art have a problem that, when a central conductor slides, separation between a sliding portion and a holding portion may occur, which leads to an increase in resistance or occurrence of unnecessary resonance. To solve this problem, Japanese Unexamined Patent Application Publication No. 2001-307811 and Japanese Unexamined Patent Application Publication No. 2003-100374 propose a structure including a plunger shaped such that an end surface thereof that is urged by a coil spring is at an angle. According to such a structure, the coil spring presses the end surface of the plunger so that the contact pressure at which the plunger is pressed against the inner surface of a tube (hole) is increased. Thus, the plunger slides while being constantly in contact with the inner side surface of the tube (hole).

### SUMMARY

The structure in which the end surface of the plunger pressed by the coil spring is at an angle as described in Japanese Unexamined Patent Application Publication No. 2001-307811 and Japanese Unexamined Patent Application Publication No. 2003-100374 is effective when the frequency band of the signal that is used is a relatively low frequency band. However, the inventors of the present disclosure have found that unnecessary resonance may occur when the frequency band of the signal is a high-frequency band, such as a microwave band or a millimeter wave band.

Accordingly, the present disclosure provides a probe that is not influenced by unnecessary resonance even when the frequency band that is used is a high-frequency band, such as a microwave band or a millimeter wave band.

A probe according to an example of the present disclosure is connected to a signal conductor of a signal cable when used and is capable of coming into contact with a signal conductor of a mating receptacle. The probe includes a barrel that is a tubular conductor and that is electrically connectable to the signal conductor of the signal cable; a plunger that is a conductor and has a proximal end and a distal end, with the proximal end being disposed in the barrel, and the distal end projecting from the barrel and being configured to come into contact with the mating receptacle; and an elastic body disposed in the barrel. The elastic body urges the proximal end of the plunger in a direction toward the distal end of the plunger. The barrel includes a contact portion that is in contact with the plunger at a position closer to a distal end of the barrel than the proximal end of the plunger.

According to the present disclosure, a probe that is not influenced by unnecessary resonance even when the frequency band that is used is a high-frequency band, such as a microwave band or a millimeter wave band, is provided.

### BRIEF DESCRIPTION OF THE DRAWINGS

FIG. 1 is a central longitudinal sectional view of a probe according to a first embodiment taken along a central axis;

FIG. 2 is a central longitudinal sectional view of an end portion of the probe illustrating, in particular, the positional relationship between a barrel and a plunger;

FIG. 3 is a front view illustrating the structure of an end portion of the barrel;

FIG. 4A is a central longitudinal sectional view of the probe before being attached to a mating receptacle, which is a test subject; and FIG. 4B is a central longitudinal sectional view of the probe after being attached to the mating receptacle;

FIGS. 5A and 5B illustrate a path of a current that flows along the plunger and the barrel;

FIGS. 6A and 6B are sectional views of a probe according to a second embodiment illustrating, in particular, a portion of a barrel, a plunger, a portion of a coil spring, and a bushing;

FIGS. 7A and 7B are sectional views of a probe according to a third embodiment illustrating, in particular, a portion of a barrel, a plunger, a portion of a coil spring, and a bushing;

FIGS. 8A and 8B are sectional views of another probe according to the third embodiment illustrating, in particular, a portion of a barrel, a plunger, a portion of a coil spring, and a bushing;

FIGS. 9A and 9B are sectional views of another probe according to the third embodiment illustrating, in particular, a portion of a barrel, a plunger, a portion of a coil spring, and a bushing;

FIGS. 10A and 10B are sectional views of a probe according to a fourth embodiment illustrating, in particular, a portion of a barrel, a plunger, a portion of a coil spring, and a bushing; and

FIGS. 11A and 11B illustrate a path of a current that flows along a plunger and a barrel of a probe according to a comparative example, where FIG. 11B is a partial enlarged view of FIG. 11A;

### DETAILED DESCRIPTION

Probes according to some aspects of the present disclosure will now be described.

A probe according to a first aspect of the present disclosure is connected to a signal conductor of a signal cable when used, and is capable of coming into contact with a signal conductor of a mating receptacle. The probe includes a barrel that is a tubular conductor and that is electrically connectable to the signal conductor of the signal cable; a plunger that is a conductor, the plunger having a proximal end disposed in the barrel and a distal end projecting from the barrel and being configured to come into (direct or indirect) contact with the mating receptacle; and an elastic body disposed in the barrel, the elastic body urging the proximal end of the plunger in a direction toward the distal end of the plunger. The barrel includes a contact portion that is in contact with the plunger at a position closer to a distal end of the barrel than the proximal end of the plunger.

According to the above-described structure, the signal path that causes unnecessary resonance is shortened so that the resonant frequency is outside the frequency band and that the influence of unnecessary resonance is reduced.

A probe according to a second aspect of the present disclosure is structured such that the plunger includes a head portion that is disposed in the barrel and that has a large diameter and a shaft portion that projects from the distal end of the barrel and that has a small diameter. The contact portion of the barrel is in contact with the shaft portion of the plunger. According to this structure, the contact surface between the plunger and the elastic body can be increased, and the sliding performance of the plunger that slides along the barrel can be maintained.

A probe according to a third aspect of the present disclosure is structured such that the contact portion of the barrel is positioned at or near the distal end of the barrel. According to this structure, the signal path from the contact portion to the distal end of the barrel is shortened, and is not complex. Therefore, unnecessary resonance is effectively reduced.

A probe according to a fourth aspect of the present disclosure is structured such that the contact portion of the barrel is a portion at which an inner diameter of the barrel is reduced. According to this structure, the contact portion of the barrel is reliably in contact with the plunger.

A probe according to a fifth aspect of the present disclosure is structured such that the barrel includes a distal end portion that is leaf-spring-shaped. According to this structure, the plunger slides while being reliably in contact with the contact portion of the barrel.

A probe according to a sixth aspect of the present disclosure is structured such that the probe further includes a conductive member that is ball-shaped or roll-shaped, the conductive member being disposed between a portion of the barrel near the distal end of the barrel and the plunger to provide electrical connection without impeding movement of the plunger in an axial direction. The contact portion of the barrel is in contact with the plunger through the conductive member. According to this structure, the plunger can be easily moved relative to the barrel in the axial direction, and the contact portion of the barrel is in stable contact with the plunger.

A probe according to a seventh aspect of the present disclosure is structured such that a surface of the plunger at the proximal end of the plunger is at an angle relative to a plane orthogonal to a central axis of the plunger. This structure provides an effect of tilting the central axis of the plunger relative to the central axis of the barrel, and the contact pressure applied to the contact portion of the barrel by the plunger is increased. Accordingly, the plunger slides while being constantly in contact with the contact portion of the barrel.

A probe according to an eighth aspect of the present disclosure is structured such that the plunger includes another contact portion that is in contact with the barrel at a position closer to the proximal end of the plunger than the contact portion of the barrel. According to this structure, the plunger stably slides in the axial direction in the barrel.

A probe according to a ninth aspect of the present disclosure is structured such that the signal cable is a coaxial cable including an inner conductor that is the signal conductor of the signal cable and an outer conductor that surrounds the inner conductor, and such that the mating receptacle is a coaxial receptacle including the signal conductor of the mating receptacle and an outer conductor. The probe further includes a conductor housing including a first outer-conductor connecting portion to be connected to the outer conductor of the coaxial cable and a second outer-conductor connecting portion to be connected to the outer conductor of the mating receptacle, the conductor housing surrounding the barrel, the plunger, and the elastic body. The probe having this structure may be used as a probe for connecting the coaxial cable to the mating receptacle.

Embodiments of the present disclosure will now be described by way of examples with reference to the drawings. In the drawings, the same elements are denoted by the same reference signs. Although the embodiments are separately described to facilitate description of features and understanding, structural components described in different embodiments may be replaced or combined with each other. In the second and following embodiments, description of elements that are the same as those in the first embodiment will be omitted, and only differences will be described. In particular, description of similar effects obtained by similar structures will not be repeated in each embodiment.

### First Embodiment

### [Structure of Probe]

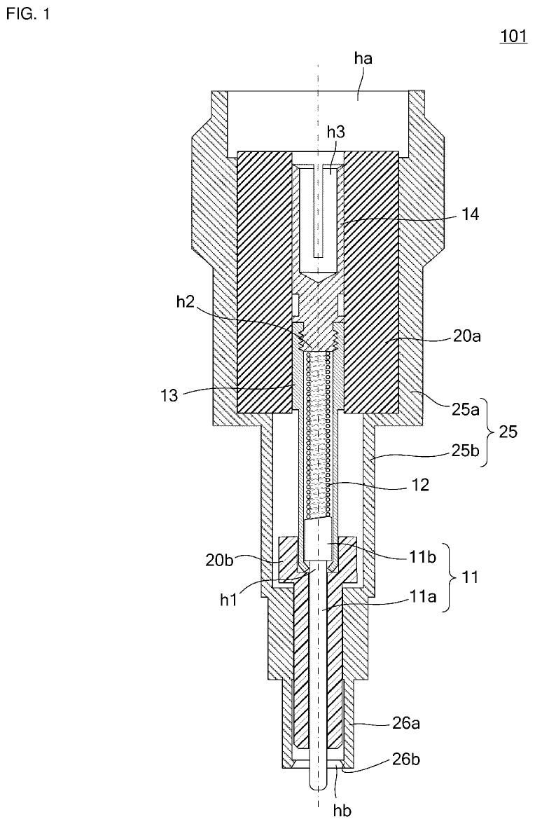

FIG. 1 is a central longitudinal sectional view of a probe 101 according to a first embodiment taken along a central axis. The probe 101 is connected to a signal conductor of a signal cable (not illustrated) when used, and is capable of coming into contact with a signal conductor of a mating receptacle (not illustrated). The signal cable is a coaxial cable including an inner conductor that is the signal conductor of the signal cable and an outer conductor that surrounds the inner conductor. As described below, the mating receptacle is a coaxial receptacle including the signal conductor of the mating receptacle and an outer conductor.

The probe 101 includes a socket 14, a barrel 13, a plunger 11, a coil spring 12, bushings 20a and 20b, and a conductor housing 25. The coil spring 12 corresponds to an “elastic body” according to the present disclosure.

The conductor housing 25 is a tubular member including an upper portion 25a and a lower portion 25b. The outer conductor of the signal cable is connected to the upper portion 25a, and the outer conductor of the signal mating receptacle is connected to the lower portion 25b. The upper portion 25a of the conductor housing 25 has an opening ha, and the lower portion 25b of the conductor housing 25 has an opening hb. The conductor housing 25 is made of, for example, beryllium copper having relatively high spring characteristics (high Young's modulus).

The lower portion 25b of the conductor housing 25 includes an end portion 26a and a projection 26b. The end portion 26a is a portion located at the lower end of the lower portion 25b, and the outer conductor of the mating receptacle, which will be described below, is inserted into the end portion 26a. The end portion 26a of the conductor housing 25 has an inner diameter less than those of portions other than the end portion 26a, and is structured such that the inner diameter thereof can be increased and reduced. More specifically, the end portion 26a has a plurality of slits that extend in an axial direction from the end of the end portion 26a. Due to the slits, the end portion 26a has spring characteristics and is radially expandable and contractible. The projection 26b projects toward the center of the end portion 26a from the inner peripheral surface of the end portion 26a.

The socket 14 is a cylindrical member and has an opening h3 at the upper end thereof. A slit that extends in the axial direction is formed in a side surface of the socket 14. The socket 14 is composed of a conductive member having relatively high spring characteristics (for example, beryllium copper). According to this structure, when the inner conductor of the signal cable is inserted into the socket 14 from above, the socket 14 is elastically expanded and pressed against the inner conductor. The socket 14 has an external thread at the lower end thereof.

The plunger 11 is a pin made of beryllium copper, and includes a shaft portion 11a and a head portion 11b. The shaft portion 11a is a rod-shaped member extending in the axial direction and having a uniform thickness. The head portion 11b is provided at the upper end of the shaft portion 11a, and has a diameter greater than that of the shaft portion 11a.

The barrel 13 holds the plunger 11 at the lower end thereof so that the plunger 11 extends along a straight line in the axial direction, and holds the socket 14 at the upper end thereof by means of a screw structure. The barrel 13 is a cylindrical member composed of a conductive member having relatively low spring characteristics (for example, brass). The barrel 13 has an opening h1 at the bottom thereof, the opening h1 having a diameter that is substantially equal to the diameter of the shaft portion 11a and less than the diameter of the head portion 11b. The barrel 13 also has an opening h2 at the upper end thereof, the opening h2 having an inner diameter greater than the outer diameter of the coil spring 12 and the diameter of the head portion 11b. The barrel 13 has an internal thread at the upper end thereof.

The plunger 11 is attached to the barrel 13 so that the shaft portion 11a projects downward out of the barrel 13 through the opening h1. In other words, the plunger 11 is inserted into the barrel 13 through the opening h2.

The coil spring 12 is an elastic member that urges the plunger 11 downward against the barrel 13. The coil spring 12 is inserted into the barrel 13 through the opening h2, and is thereby disposed in the barrel 13. Thus, when the plunger 11 is pressed from below, the coil spring 12 contracts to enable the plunger 11 to be retracted upward.

The socket 14 is fixed to the barrel 13 to which the plunger 11 and the coil spring 12 are attached by means of a screw structure.

The bushings 20a and 20b are tubular bodies composed of insulators made of, for example, a resin, and are disposed in the conductor housing 25. The bushing 20a fixes the socket 14 and a portion of the barrel 13 to the upper portion 25a of the conductor housing 25. The bushing 20b holds the shaft portion 11a of the plunger 11 in the lower portion 25b of the conductor housing 25 such that the shaft portion 11a is slidable in the axial direction.

The bushings 20a and 20b are composed of insulators, and therefore the barrel 13 and the plunger 11 are insulated from the conductor housing 25.

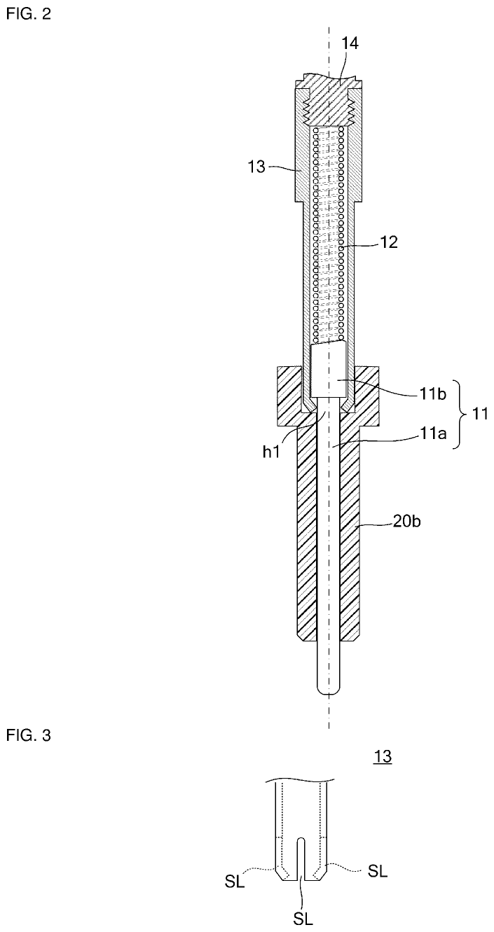

FIG. 2 is a central longitudinal sectional view of an end portion of the probe 101 illustrating, in particular, the positional relationship between the barrel 13 and the plunger 11. FIG. 3 is a front view illustrating the structure of an end portion of the barrel 13. The opening h1 at the end of the barrel 13 has a reduced inner diameter. The end portion of the barrel 13 that surrounds the head portion 11b of the plunger 11 has four slits SL, and is therefore radially elastic. As described below, the end portion of the barrel 13 having a reduced inner diameter serves as a contact portion that is in contact with the shaft portion 11a of the plunger 11.

[Attachment and Removal of Probe to and from Mating Receptacle]

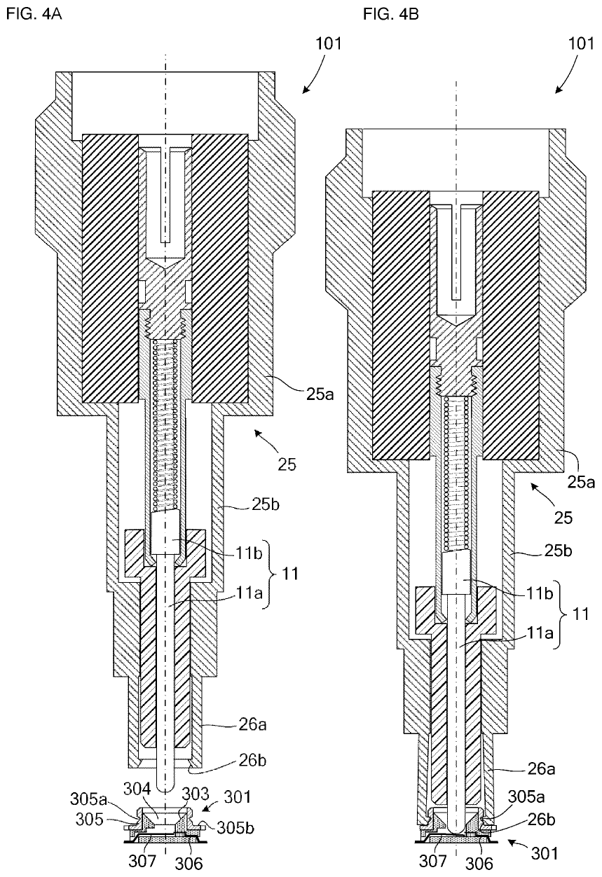

Attachment and removal of the probe 101 to and from the mating receptacle will now be described with reference to FIGS. 4A and 4B. FIG. 4A is a central longitudinal sectional view of the probe 101 before being attached to a mating receptacle 301, which is a test subject, and FIG. 4B is a central longitudinal sectional view of the probe 101 after being attached to the mating receptacle 301.

The mating receptacle 301 will now be described. The mating receptacle 301 is, for example, a coaxial connector having a switch provided between an antenna and a transmission/reception circuit of a cellular phone, and includes a casing 303, an outer conductor 305, a fixed terminal 306, and a movable terminal 307. The fixed terminal 306 is connected to the antenna, and the movable terminal 307 is connected to the transmission/reception circuit.

As illustrated in FIG. 4A, when the probe 101 is not attached to the mating receptacle 301, the shaft portion 11a of the plunger 11 projects downward from the end portion 26a of the conductor housing 25. In this state, the fixed terminal 306 and the movable terminal 307 of the mating receptacle 301 are in contact with each other, so that the antenna and the transmission/reception circuit are connected to each other.

Referring to FIGS. 4A and 4B, when the probe 101 is attached to the mating receptacle 301, the end of the shaft portion 11a of the plunger 11, to which a measurement device is connected through a coaxial cable, is inserted into a hole 304 in the casing 303 downward from above. Accordingly, the movable terminal 307 is pressed downward by the shaft portion 11a of the plunger 11. As a result, the fixed terminal 306 and the movable terminal 307 are separated from each other, and the plunger 11 is connected to the movable terminal 307, so that the transmission/reception circuit is connected to the measurement device.

In the state illustrated in FIG. 4B, the outer conductor 305 is inserted in the end portion 26a of the conductor housing 25. The inner diameter of the end portion 26a is slightly less than the outer diameter of the outer conductor 305 before the insertion of the outer conductor 305. Therefore, the end portion 26a is slightly expanded by the outer conductor 305 during and after the insertion of the outer conductor 305. The projection 26b engages with a groove 305a formed in the outer periphery of the outer conductor 305, and the end portion 26a comes into contact with an upper surface 305b of the outer conductor 305. Thus, the probe 101 is engaged with the mating receptacle 301 by an appropriate force.

The end portion 26a of the conductor housing 25 corresponds to a “second outer-conductor connecting portion” according to the present disclosure. The outer conductor of the coaxial cable is connected to the upper end of the upper portion 25a of the conductor housing 25. The upper portion 25a of the conductor housing 25 corresponds to a “first outer-conductor connecting portion” according to the present disclosure. The probe 101 having the above-described structure may be used as a probe for connecting the coaxial cable to the mating receptacle 301.

### [Current Path Through Probe]

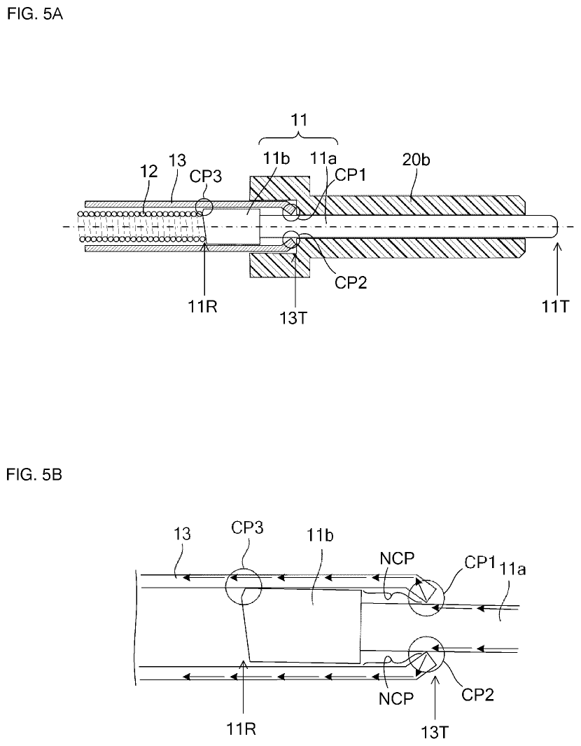

FIGS. 5A and 5B illustrate a path of a current that flows along the plunger 11 and the barrel 13. FIG. 5A illustrates contact portions of the barrel when the probe 101 is attached to the mating receptacle 301 as illustrated in FIG. 4B. FIG. 5B is a partial enlarged view of FIG. 5A.

The plunger 11 includes the head portion 11b, which is disposed in the barrel 13 and has a large diameter, and the shaft portion 11a, which projects from a distal end 13T of the barrel 13 and has a small diameter. The plunger 11 has a proximal end 11R and a distal end 11T. The proximal end 11R is disposed in the barrel 13, and the distal end 11T projects from the barrel 13. The barrel 13 has contact portions CP1 and CP2 that are in contact with the shaft portion 11a of the plunger 11 at positions closer to the distal end 13T of the barrel 13 than the proximal end 11R of the plunger 11. In other words, the contact portions CP1 and CP2 of the barrel 13 are in contact with the shaft portion 11a of the plunger 11. In the present embodiment, the contact portions CP1 and CP2 are spaced from the head portion 11b of the plunger 11. In other words, the barrel 13 has a non-contact portion NCP that is not in direct contact with the plunger 11 (shaft portion 11a of the plunger) in a region between the head portion 11b of the plunger and the contact portions CP1 and CP2. The contact portions CP1 and CP2 of the barrel 13 are portions at which the inner diameter of the barrel 13 is reduced.

In the present embodiment, the contact portions CP1 and CP2 of the barrel 13 are positioned at or near the distal end 13T of the barrel 13. In other words, the barrel 13 is in contact with the shaft portion 11a of the plunger 11 at or near the distal end thereof.

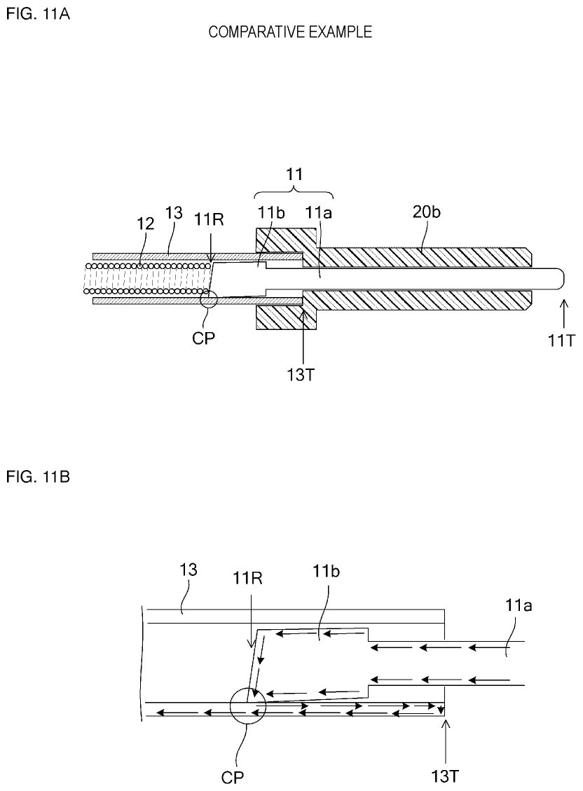

A probe according to a comparative example will now be described with reference to FIGS. 11A and 11B. FIGS. 11A and 11B illustrate a path of a current that flows along a plunger 11 and a barrel 13 of a probe according to a comparative example. FIG. 11B is a partial enlarged view of FIG. 11A. The probe of this comparative example is structured such that the plunger 11 includes a head portion 11b, which is disposed in the barrel 13 and has a large diameter, and a shaft portion 11a, which projects from a distal end 13T of the barrel 13 and has a small diameter. The head portion 11b of the plunger 11 is in contact with the inner surface of the barrel 13. The contact portion CP illustrated in FIGS. 11A and 11B shows the contact position.

Referring to FIG. 11B, the arrows superimposed on the shaft portion 11a and the head portion 11b of the plunger 11 and the barrel 13 show a current path. A high-frequency signal is transmitted by an electric field between an inner conductor and an outer conductor. Therefore, a current flows along the surfaces of the shaft portion 11a of the plunger and the barrel 13, which constitute the inner conductor.

In the probe according to the related art, the signal current flows along the plunger 11 and the barrel 13 through the contact position between the head portion 11b of the plunger and the barrel 13. Therefore, a long, unnecessary current path is generated between the proximal end 11R of the plunger 11 and the distal end 13T of the barrel 13. Such a current path causes unnecessary resonance.

In FIG. 5B, the arrows superimposed on the shaft portion 11a of the plunger 11 and the barrel 13 show a current path. As described above, a high-frequency signal is transmitted by an electric field between an inner conductor and an outer conductor, and therefore a current flows along the surfaces of the shaft portion 11a of the plunger and the barrel 13, which constitute the inner conductor. In the present embodiment, the barrel 13 is in contact with the shaft portion 11a of the plunger 11 at a position closer to the distal end 13T of the barrel 13 than the proximal end 11R of the plunger 11. Therefore, the unnecessary current path from the proximal end 11R of the plunger 11 to the distal end 13T of the barrel 13 illustrated in FIG. 11B is not formed, and unnecessary resonance is reduced. Even when an unnecessary current path is generated, the length thereof is short. Therefore, the frequency of the unnecessary resonance is higher than the used frequency band, so that the unnecessary resonance does not cause adverse effects at the used frequency.

In the present embodiment, the surface of the proximal end 11R of the plunger 11 is at an angle relative to a pane orthogonal to the central axis of the plunger 11 (one-dot chain line). This structure provides an effect of tilting the central axis of the plunger 11 relative to the central axis of the barrel 13 (one-dot chain line). In the sectional views illustrated in FIGS. 5A and 5B, the plunger 11 receives a clockwise force so that the contact pressure applied to the contact portion CP2 of the barrel 13 by the plunger 11 is increased. This enables the plunger 11 to slide while being reliably in contact with the contact portion CP2 of the barrel 13.

In the present embodiment, since the plunger 11 receives the clockwise force as described above, the plunger 11 is in contact with the barrel 13 at a contact portion CP3 positioned closer to the proximal end 11R of the plunger 11 than the contact portions CP1 and CP2 of the barrel 13. This contact portion CP3 corresponds to “another contact portion” according to the present disclosure. According to this structure, the plunger 11 is in contact with the barrel 13 at the contact portion CP2 and the contact portion CP3, which are located diagonally to each other in the sectional view. Therefore, the plunger 11 stably slides in the axial direction in the barrel 13.

It is not necessary that the contact portion CP1 of the barrel 13 be constantly in contact with the plunger 11. The above-described force may be applied such that the plunger 11 is in contact with the contact portions CP2 and CP3 of the barrel 13 but is not in contact with the contact portion CP1.

Although four slits SL are provided in the example illustrated in FIG. 3, the number of slits SL may instead be one, two, or five or more.

### Second Embodiment

A probe of a second embodiment, which includes a plunger and a barrel having shapes different from those in the first embodiment, will now be described.

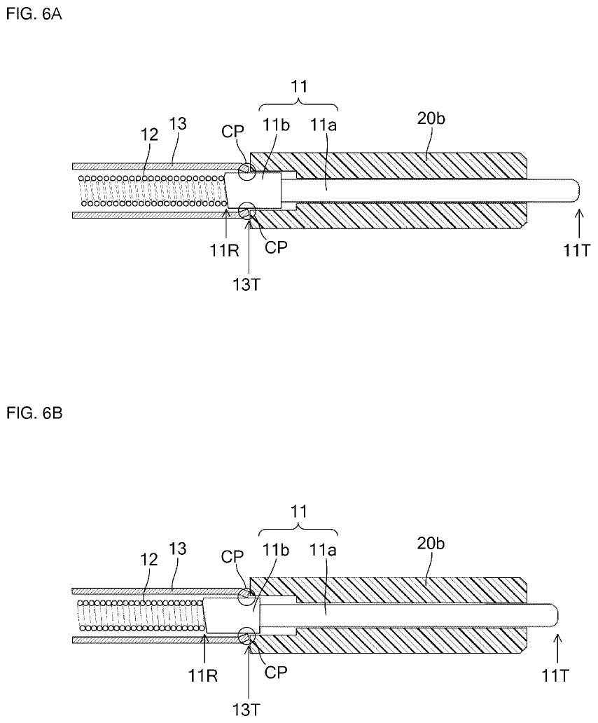

FIGS. 6A and 6B are sectional views of a probe according to the present embodiment illustrating, in particular, a portion of a barrel 13, a plunger 11, a portion of a coil spring 12, and a bushing 20b. Other structures are the same as those of the probe according to the first embodiment illustrated in FIGS. 1, 4A, and 4B.

FIG. 6A illustrates the positional relationship between the components when the probe is not attached to the mating receptacle, as illustrated in FIG. 4A. FIG. 6B shows the positional relationship between the components when the probe is attached to the mating receptacle, as illustrated in FIG. 4B.

The plunger 11 includes a head portion 11b, which is partially disposed in the barrel 13 and has a large diameter, and a shaft portion 11a, which projects from a distal end 13T of the barrel 13 and has a small diameter. The plunger 11 has a proximal end 11R and a distal end 11T. The proximal end 11R is disposed in the barrel 13, and the distal end 11T projects from the barrel 13. The barrel 13 has contact portions CP that are in contact with the head portion 11b of the plunger 11 at positions closer to the distal end 13T of the barrel 13 than the proximal end 11R of the plunger 11. In other words, the contact portions CP of the barrel 13 are in contact with the head portion 11b of the plunger 11. The contact portions CP of the barrel 13 are portions at which the inner diameter of the barrel 13 is reduced.

In the present embodiment, the contact portions CP of the barrel 13 are positioned at or near the distal end 13T of the barrel 13. In other words, the barrel 13 is in contact with the head portion 11b of the plunger 11 at or near the distal end thereof.

Also in the present embodiment, the unnecessary current path from the proximal end 11R of the plunger 11 to the distal end 13T of the barrel 13 illustrated in FIG. 11B is not formed, and unnecessary resonance is reduced.

### Third Embodiment

Probes of a third embodiment, which each include a barrel having contact portions whose shapes differ from those in the above-described examples, will now be described.

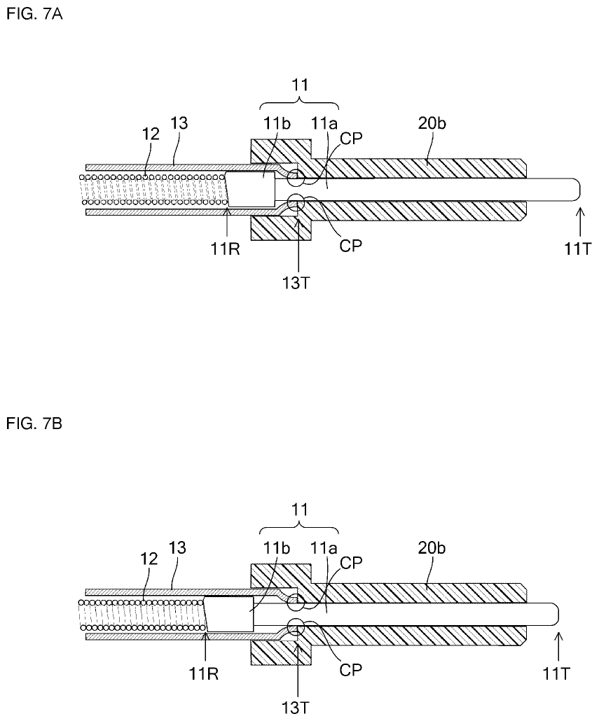

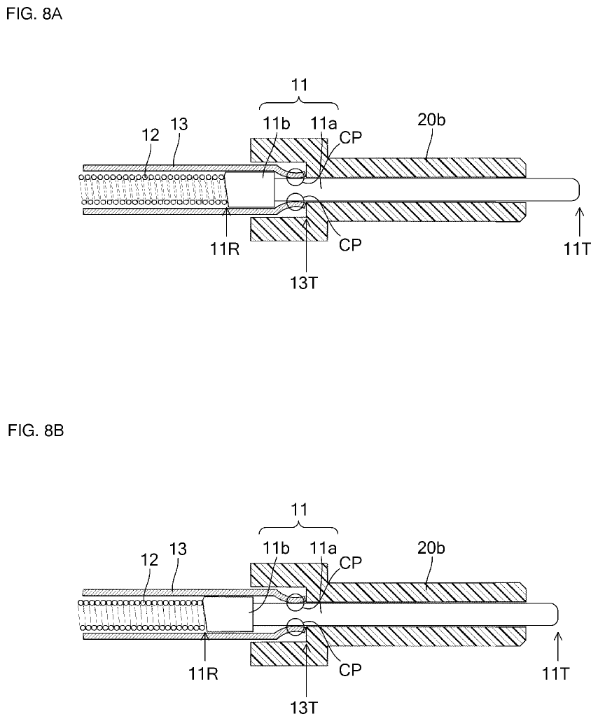

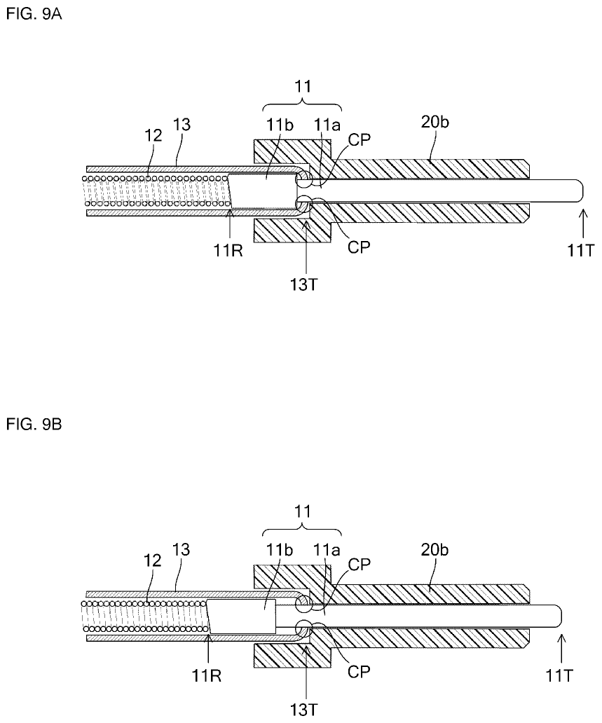

FIGS. 7A and 7B are sectional views of a probe according to the third embodiment illustrating, in particular, a portion of a barrel 13, a plunger 11, a portion of a coil spring 12, and a bushing 20b. FIGS. 8A and 8B are sectional views of another probe according to the third embodiment illustrating, in particular, a portion of a barrel 13, a plunger 11, a portion of a coil spring 12, and a bushing 20b. FIGS. 9A and 9B are sectional views of another probe according to the third embodiment illustrating, in particular, a portion of a barrel 13, a plunger 11, a portion of a coil spring 12, and a bushing 20b. Structures other than those illustrated in FIGS. 7A, 7B, 8A, 8B, 9A, and 9B are the same as those of the probe according to the first embodiment illustrated in FIGS. 1, 4A, and 4B.

FIGS. 7A, 8A, and 9A illustrate the positional relationship between the components when the probe is not attached to the mating receptacle, as illustrated in FIG. 4A. FIGS. 7B, 8B, and 9B show the positional relationship between the components when the probe is attached to the mating receptacle, as illustrated in FIG. 4B.

In each of the probes illustrated in FIG. 7A, 7B, 8A, 8B, 9A, or 9B, the plunger 11 includes a head portion 11b, which is disposed in the barrel 13 and has a large diameter, and a shaft portion 11a, which projects from a distal end 13T of the barrel 13 and has a small diameter. The plunger 11 has a proximal end 11R and a distal end 11T. The proximal end 11R is disposed in the barrel 13, and the distal end 11T projects from the barrel 13. The barrel 13 has contact portions CP that are in contact with the shaft portion 11a of the plunger 11 at positions closer to the distal end 13T of the barrel 13 than the proximal end 11R of the plunger 11. In other words, the contact portions CP of the barrel 13 are in contact with the shaft portion 11a of the plunger 11. In the examples illustrated in FIGS. 7A, 7B, 9A, and 9B, the contact portions CP of the barrel 13 are portions at which the barrel 13 is narrowest at the distal end 13T. In the example illustrated in FIGS. 8A and 8B, the contact portions CP of the barrel 13 are portions at which the barrel 13 is narrowest at a position slightly in front of the distal end 13T. The barrel 13 has a distal end portion (end portion including the distal end 13T) that is leaf-spring-shaped.

Also in the present embodiment, the unnecessary current path from the proximal end 11R of the plunger 11 to the distal end 13T of the barrel 13 illustrated in FIG. 11B is not formed, and unnecessary resonance is reduced. In addition, in the present embodiment, the plunger 11 slides while being reliably in contact with the contact portions CP of the barrel 13.

### Fourth Embodiment

A probe according to a fourth embodiment, which includes ball-shaped or roll-shaped conductive members between a portion of a barrel near the distal end of the barrel and a plunger, will now be described.

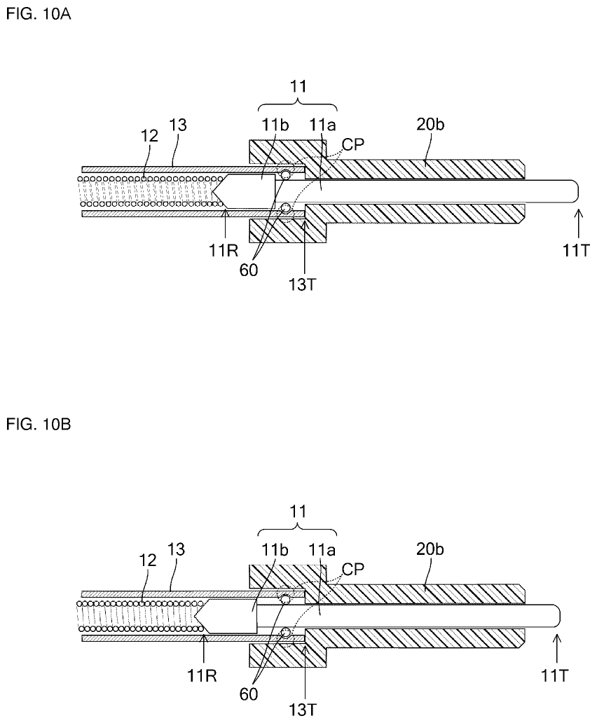

FIGS. 10A and 10B are sectional views of a probe according to the fourth embodiment illustrating, in particular, a portion of a barrel 13, a plunger 11, a portion of a coil spring 12, and a bushing 20b.

The plunger 11 includes a head portion 11b, which is partially disposed in the barrel 13 and has a large diameter, and a shaft portion 11a, which projects from a distal end 13T of the barrel 13 and has a small diameter. The plunger 11 has a proximal end 11R and a distal end 11T. The proximal end 11R is disposed in the barrel 13, and the distal end 11T projects from the barrel 13. The barrel 13 has contact portions CP that are in contact with the head portion 11b of the plunger 11 at positions closer to the distal end 13T of the barrel 13 than the proximal end 11R of the plunger 11. More specifically, ball-shaped or roll-shaped conductive members 60 are disposed between a portion of the barrel 13 near the distal end 13T and the plunger 11 to provide electrical connection without impeding movement of the plunger 11 in the axial direction. The contact portions CP of the barrel 13 are in contact with the plunger 11 through the conductive members 60. Other structures are the same as those of the probe according to the first embodiment illustrated in FIGS. 1, 4A, and 4B.

FIG. 10A illustrates the positional relationship between the components when the probe is not attached to the mating receptacle, as illustrated in FIG. 4A. FIG. 10B shows the positional relationship between the components when the probe is attached to the mating receptacle, as illustrated in FIG. 4B.

According to the present embodiment, the plunger 11 can be easily moved relative to the barrel 13 in the axial direction, and the contact portions CP of the barrel 13 are in stable contact with, or in stable electrical connection with, the plunger 11.

The above description of the embodiments is illustrative in all respects and is not restrictive. Modifications and alterations are possible by those skilled in the art. The scope of the present disclosure is defined not by the above-described embodiments, but by the claims. In addition, the scope of the present disclosure includes alterations to the embodiments within the equivalents to the scope of the claims.

For example, in the first to third embodiments, the contact portions CP disposed near the distal end 13T of the barrel 13 are portions at which the inner diameter of the barrel 13 is reduced. The portions at which the inner diameter is reduced may be composed of a component different from the portion of the barrel 13 having a constant inner diameter. The leaf-spring-shaped portion of the barrel 13, which is a portion at the distal end 13T, may be composed of a component different from the portion of the barrel 13 having a constant inner diameter. In other words, the barrel 13 may be obtained by joining a component having a constant inner diameter and another component having a reduced inner diameter.

What is claimed is:

1. A probe that is connected to a signal conductor of a signal cable when used and that is capable of coming into contact with a signal conductor of a mating receptacle, the probe comprising:
a barrel that is a tubular conductor and that is electrically connectable to the signal conductor of the signal cable;
a plunger that is a conductor, the plunger having a proximal end and a distal end, the proximal end being disposed in the barrel, the distal end projecting from the barrel and being configured to come into contact with the mating receptacle; and
an elastic body disposed in the barrel, the elastic body being configured to urge the proximal end of the plunger in a direction toward the distal end of the plunger,
wherein the barrel includes a contact portion that is in contact with the plunger at a position closer to a distal end of the barrel than the proximal end of the plunger.

2. The probe according to claim 1, wherein
the plunger includes a head portion that is disposed in the barrel and that has a large diameter and a shaft portion that projects from the distal end of the barrel and that has a small diameter, and
the contact portion of the barrel is in contact with the shaft portion of the plunger.

3. The probe according to claim 2, wherein
the barrel includes a non-contact portion that is positioned between the head portion of the plunger and the contact portion of the barrel and that is not in contact with the plunger.

4. The probe according to claim 1, wherein
the contact portion of the barrel is positioned at or near the distal end of the barrel.

5. The probe according to claim 1, wherein
the contact portion of the barrel is a portion at which an inner diameter of the barrel is reduced.

6. The probe according to claim 5, wherein
the barrel includes a distal end portion that is leaf-spring-shaped.

7. The probe according to claim 1, further comprising:
a conductive member that is ball-shaped or roll-shaped, the conductive member being disposed between a portion of the barrel near the distal end of the barrel and the plunger to provide electrical connection without impeding movement of the plunger in an axial direction, and
wherein the contact portion of the barrel is in contact with the plunger through the conductive member.

8. The probe according to claim 1, wherein
a surface of the plunger at the proximal end of the plunger is at an angle relative to a plane orthogonal to a central axis of the plunger.

9. The probe according to claim 1, wherein
the plunger includes another contact portion that is in contact with the barrel at a position closer to the proximal end of the plunger than the contact portion of the barrel.

10. The probe according to claim 1, wherein
the signal cable is a coaxial cable including an inner conductor that is the signal conductor of the signal cable and an outer conductor that surrounds the inner conductor,
the mating receptacle is a coaxial receptacle including the signal conductor of the mating receptacle and an outer conductor, and
the probe further comprises a conductor housing including a first outer-conductor connecting portion to be connected to the outer conductor of the coaxial cable and a second outer-conductor connecting portion to be connected to the outer conductor of the mating receptacle, the conductor housing surrounding the barrel, the plunger, and the elastic body.

11. The probe according to claim 2, wherein
the contact portion of the barrel is positioned at or near the distal end of the barrel.

12. The probe according to claim 3, wherein
the contact portion of the barrel is positioned at or near the distal end of the barrel.

13. The probe according to claim 2, wherein
the contact portion of the barrel is a portion at which an inner diameter of the barrel is reduced.

14. The probe according to claim 3, wherein
the contact portion of the barrel is a portion at which an inner diameter of the barrel is reduced.

15. The probe according to claim 4, wherein
the contact portion of the barrel is a portion at which an inner diameter of the barrel is reduced.

16. The probe according to claim 2, further comprising:
a conductive member that is ball-shaped or roll-shaped, the conductive member being disposed between a portion of the barrel near the distal end of the barrel and the plunger to provide electrical connection without impeding movement of the plunger in an axial direction, and
wherein the contact portion of the barrel is in contact with the plunger through the conductive member.

17. The probe according to claim 3, further comprising:
a conductive member that is ball-shaped or roll-shaped, the conductive member being disposed between a portion of the barrel near the distal end of the barrel and the plunger to provide electrical connection without impeding movement of the plunger in an axial direction, and
wherein the contact portion of the barrel is in contact with the plunger through the conductive member.

18. The probe according to claim 2, wherein
a surface of the plunger at the proximal end of the plunger is at an angle relative to a plane orthogonal to a central axis of the plunger.

19. The probe according to claim 2, wherein
the plunger includes another contact portion that is in contact with the barrel at a position closer to the proximal end of the plunger than the contact portion of the barrel.

20. The probe according to claim 2, wherein
the signal cable is a coaxial cable including an inner conductor that is the signal conductor of the signal cable and an outer conductor that surrounds the inner conductor,
the mating receptacle is a coaxial receptacle including the signal conductor of the mating receptacle and an outer conductor, and
the probe further comprises a conductor housing including a first outer-conductor connecting portion to be connected to the outer conductor of the coaxial cable and a second outer-conductor connecting portion to be connected to the outer conductor of the mating receptacle, the conductor housing surrounding the barrel, the plunger, and the elastic body.
